(19) United States
(12) Patent Application Publication
(10) Pub. No.: US 2025/0299943 A1
(43) Pub. Date: Sep. 25, 2025

(54) ION BEAM COLUMN ION SPECIES MEASUREMENT

(71) Applicant: FEI Company, Hillsboro, OR (US)

(72) Inventors: Daniel TOTONJIAN, Hillsboro, OR (US); Kevin KAGARICE, Hillsboro, OR (US)

(73) Assignee: FEI Company, Hillsboro, OR (US)

(21) Appl. No.: 18/612,557

(22) Filed: Mar. 21, 2024

(51) Int. Cl. H01J 49/42

(52) U.S. Cl. CPC H01J 49/4245

(57) ABSTRACT

A charged particle system including a plasma source configured to generate an ion beam including a plurality of ion species and an ion beam optics chamber in fluid communication with the plasma source. The ion beam optics chamber includes an electromagnetic element configured to generate a first magnetic field to separate each of the ion species of the plurality of ion species and a conductive container configured to measure a first current corresponding to a first ion species of the plurality of ion species.

### BACKGROUND

Charged particle beam systems are used in a variety of applications including the manufacturing, repair, and inspection of miniature devices, such as integrated circuits, magnetic recording heads, and photolithography masks. In a certain type of charged particle beam system, ions are generated by ionizing a gas in a plasma source. These ions are then directed towards the sample in a beam to perform a processing or imaging step, as well as make physical alterations to the sample. The ion species utilized for this purpose can be tailored to a specific sample or process by altering the gas species ionized in the plasma source. Certain samples or processes may require a mixture of multiple unique ion species. This mixed-species ion beam can be generated by a plasma source derived from a mixture of multiple unique gas species. New charged particle beam systems optimizing the measurement of this mixed-species ion beam are desired.

### BRIEF SUMMARY

One aspect of the disclosure provides for a charged particle system including a plasma source configured to generate an ion beam including a plurality of ion species and an ion beam optics chamber in fluid communication with the plasma source. The ion beam optics chamber includes an electromagnetic element configured to generate a first magnetic field to separate each of the ion species of the plurality of ion species and a conductive container configured to measure a first current corresponding to a first ion species of the plurality of ion species.

Implementations may include one or more of the following features. The charged particle system may include a computer system in communication with the conductive container, where the computer system is configured to determine a first mass of a first gas species corresponding to the first ion species based on the first current. The sample holder may include a sample holder, where: in a first state, the plasma source generates the ion beam and the ion beam is directed to the sample holder; and in a second state, the electromagnetic element generates the first magnetic field and the sample chamber is free of the ion beam. In the second state, the ion beam optics chamber and the sample chamber may be fluidly isolated from each other. The charged particle system may include an aperture plate that defines an aperture configured to receive the first ion species while the aperture plate is configured to block other ion species of the plurality of ion species. The charged particle system may include an electrostatic element configured to generate an electrostatic field to deflect the first ion species toward the aperture of the aperture plate. The aperture plate may be movable to align the aperture with the first ion species. The aperture plate may include the conductive container.

Another aspect of the disclosure provides for a charged particle system a plasma source and an ion beam optics chamber including an electromagnetic element configured to generate a first magnetic field to separate a plurality of ion species of the ion beam and a conductive container configured to measure a first current of a first ion species of the plurality of ion species, where the ion beam optics chamber defines a beam inlet and a beam outlet. In a first state, the plasma source is configured to emit the ion beam through the beam inlet and the beam outlet. In a second state, the plasma source is configured to emit the ion beam through the beam inlet and at least a portion of the first ion species deviates away from the beam outlet toward the conductive container.

Implementations may include one or more of the following features. The charged particle system may include a sample chamber including a sample holder, where: in the first state, the ion beam optics chamber and the sample chamber are in fluid communication with each other; and in the second state, the ion beam optics chamber and the sample chamber are fluidly isolated from each other. The charged particle system may include a computer system in communication with the conductive container. The computer system may be configured to determine a first mass of a first gas species of the first ion species based on the first current. The charged particle system may include an aperture plate that defines an aperture configured to receive the first ion species while the aperture plate is configured to block other ion species of the plurality of ion species. The charged particle system may include an electrostatic element configured to generate an electrostatic field to deflect the first ion species toward the aperture of the aperture plate. The aperture plate may be movable to align the aperture with the first ion species. The aperture plate may include the conductive container.

Yet another aspect of the disclosure provides for a method of measuring ion species. The method of measuring ion species includes emitting, from a plasma housed in an ion source generated from a plurality of gas species, an ion beam through a beam inlet of an ion beam optics chamber. The method also includes generating, using an electromagnetic element in the ion beam optics chamber, an electromagnetic field to separate a plurality of ion species of the ion beam. The method also includes measuring, using a conductive container in the ion beam optics chamber, a first current of a first ion species of the plurality of ion species. Other embodiments of this aspect include corresponding computer systems, apparatus, and computer programs recorded on one or more computer storage devices, each configured to perform the actions of the methods.

Implementations may include one or more of the following features. The ion beam may be a first ion beam and the method may include: adjusting a first flow rate of a first gas species of the plurality of gas species corresponding to the first ion species based on the first current; and after adjusting the first flow rate, emitting a second beam from the plasma. The method may include receiving the first ion species through an aperture defined by an aperture plate. The method may include generating, using an electrostatic element, a first electrostatic field to deflect the first ion species toward the aperture. Measuring the first current of the first ion species may be performed while the ion beam optics chamber is fluidly isolated from a sample chamber.

### BRIEF DESCRIPTION OF THE DRAWINGS

A further understanding of the nature and advantages of various embodiments may be realized by reference to the following figures. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 depicts a simplified cross-sectional view of an example charged particle system.

FIG. 2A depicts a simplified cross-sectional view of an example charged particle system according to an embodiment of the disclosure.

FIG. 2B depicts the charged particle system of FIG. 2A measuring a first ion species according to an embodiment of the disclosure.

FIG. 3A depicts a simplified cross-sectional view of an example charged particle system according to an embodiment of the disclosure.

FIG. 3B depicts the charged particle system of FIG. 3A measuring a first ion species according to an embodiment of the disclosure.

FIG. 4 depicts a flowchart for measuring ion species in a beam column according to an embodiment of the disclosure.

FIG. 5 depicts a block diagram of an example computer system usable with systems and methods according to embodiments of the present disclosure.

### DETAILED DESCRIPTION

An ion beam system is a type of charged particle beam system used to perform various operations, such as imaging, processing, and/or machining operations on a sample (e.g., incising, milling, etching, depositing, or the like). In particular, focused ion beams (FIBs) mill by physically removing atoms and molecules from the surface of a sample through a process known as physical sputtering. FIB systems generally operate by directing a focused beam of ions over the surface of a sample, such as a raster pattern. In one example, these ions can be extracted from a plasma source, and accelerated and focused onto the sample using a series of apertures and electrostatic lenses. Specifically, these plasma sources ionize a gas, or mixture of gases, in a plasma source chamber and extract ions to form a beam that is focused on a sample. As the material of a sample, or the process being performed on that material, may require an ion beam made of a specific ratio of ion species that correspond to a particular ratio of gas species, the ratio of gas species used to generate the ion beam is critical to create a mixed-species ion beam that optimally mills the sample.

However, controlling for the gas species composition used in forming the plasma does not guarantee, by itself, that the mixed-species ion beam will have the desired ratio of ion species in the ion beam. For example, the ion beam can include impurities, such as any non-primary and/or undesired ion species. This can include gas remnants from a previously-used gas that remain after switching between gas species of the primary ion species. While attempts are made at purging these impurities, it can be difficult to ensure that all of the impurities have been purged. Additionally, impurities such as undesired isotopes of the primary species may also be present. Further, the trial and error involved in generating the ion beam with a desired ion species ratio can be costly due to the amount of purging of expensive gases and slow due to the time required to remove the previous gas mixture. Moreover, the final composition of ion species in the ion beam may not correlate in a straightforward and predictable manner to the initial composition of gases in the plasma source. It can thus be difficult to achieve the desired ratio of ion species based solely upon choice of input gas levels. As such, it is important to measure the ion ratio in the ion beam to ensure that the ion beam includes the desired ratio of ion species and to ensure optimal sample milling with minimal trial and error.

In one example, the ion ratio in the mixed-species ion beam can be measured in the sample chamber, after the ion beam leaves the ion beam column. In this example, the sample chamber can include a magnetic immersion lens and a current collector (e.g., a Faraday cup). The magnetic immersion lens is activated to generate a magnetic immersion field to split the ion beam into individual ion species that respectively correspond to the individual gas species used to generate the mixed-species ion beam. The current of each of those beam components can be measured by the current collector and compared to each other to determine the ion ratio of the ion beam.

However, this method includes certain drawbacks. For example, the sample chamber requires certain measurement components or modifications to other components that the sample chamber would not normally have except to be used in measuring the ion ratio of the ion beam, such as an insertable or retractable conductive container. Components to create spatial separation between ion species, such as a magnetic immersion lens, are also needed. Additionally, as the measurement is performed at the sample plane, the conductive container in the sample chamber needs to be moved in and out of the sample chamber or, otherwise, in and out of the path of the ion beams. Further, sometimes certain features in the sample chamber must be moved around to allow for the measurement to take place, such as moving the sample or sample holder away from the path of the ion beam. Even further, the components of the sample chamber required for use in milling a sample needs to be modified in order for the ion species to be measured in the sample chamber. For example, the sample stage must be modified with additional electrical connections, such as a connection to the microscope ground plane as well as connection to a current measuring device, whereas typically, only a connection to a current measuring device is required. As such, this method includes additional components that occupy valuable space in the sample chamber that can be used for additional detectors, manipulators, gas injection systems, or the like. This method also increases the complexity of use of other components in the sample chamber which must be coordinated to prevent collision or interference during the measurement.

Another drawback is that the sample chamber requires a particular set of environmental conditions in order for consistent measurement of the ion species. For example, the sample chamber must be under vacuum in order to minimize scattering of the ion species en route to the conductive container. This prevents parallel processing operations such as sample loading and unloading during the measurement. In another example, the trajectory of the ion species can be affected by the type and position of the sample holder, the position of the conductive container, the changing magnetic field in the sample chamber, and even the position and type of sample. As such, the calibration of the measurement would only be applicable for one specific sample, holder, and chamber configuration. Recalibration of the measurement would have to performed following every configuration change which would prove challenging and time consuming.

The present disclosure provides a charged particle system that measures the ion species of the mixed-species ion beam in the ion beam column, rather than the sample chamber. This includes adding an electromagnetic element and, in some embodiments, an electrostatic element, into the ion beam column in order to separate and deflect the ion species of the ion beam. The ion beam column can include a conductive container to measure the current of the ion species in the ion beam column. As will be discussed further below, measuring the ion species in the ion beam column is advantageous as the ion beam column is a more controlled environment than the sample chamber, thus allowing for a more consistent measurement.

Although the remaining portions of the description will routinely reference FIB systems, it will be readily understood by the skilled artisan that the technology is not so limited. The present designs may be employed with other types of charged particle microscope, such as scanning electron microscopes (SEM), transmission electron microscope (TEM), scanning transmission electron microscope (STEM), dual beam systems including an ion beam source and an electron beam source, reflection electron microscopes (REM), circuit editing microscopes, or the like. Accordingly, the disclosure and claims are not to be considered limited to any particular example microscope discussed, but can be utilized broadly with any number of charged particle microscopes that may exhibit some or all of the electrical or chemical characteristics of the discussed examples.

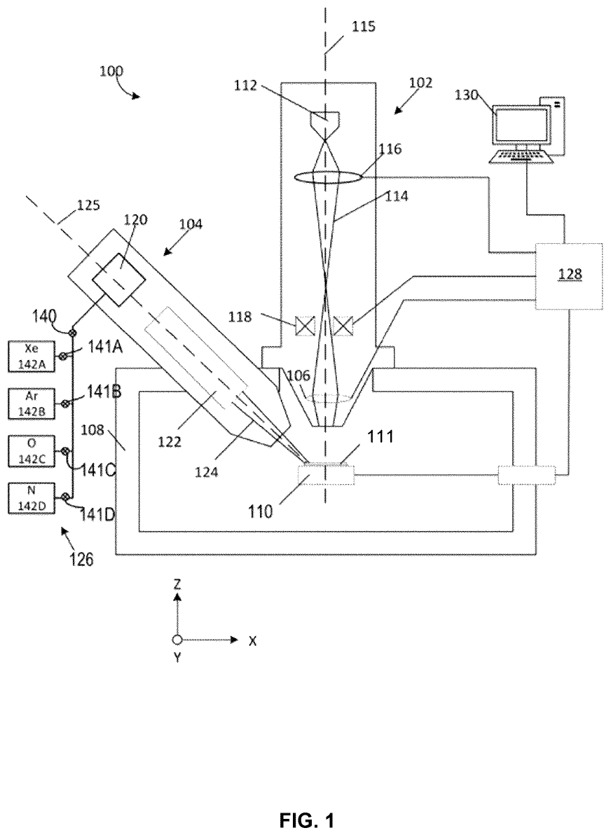

FIG. 1 depicts an example charged particle system 100 performing operations on a sample 111. The charged particle system 100 may be a dual-beam system that includes a SEM 102 that generates an electron beam and ion beam column 104 that generates a FIB. It is understood that the charged particle system 100 depicted in FIG. 1 may include additional details and components not shown.

The SEM 102 can include one or more lenses such as a condenser lens 116 and an objective lens 106 to focus an electron beam 114 from an electron source 112 along a particle-optical axis 115 to generate an image of the sample 111. In some embodiments, the SEM 102 can be provided with a deflection unit 118 that can be configured to steer the electron beam 114.

The ion beam column 104 can include an ion source 120, such as a plasma source, and an ion beam optics chamber 122. The ion source 120 can be fluidly coupled to a plurality of gases via a gas manifold 126 that includes gas sources 142A-142D coupled by respective valves 141A-141D to the ion source 120. A valve 140 is situated to selectively couple gases from the gas manifold 126 to the ion source 120. Exemplary gases include, but are not limited to, xenon, argon, oxygen, and nitrogen. During operation of the ion source 120, a gas can be introduced from one or more of the gas sources 142A-142D, where it becomes ionized, thereby forming a plasma. Ions extracted from the plasma can then be accelerated through the ion beam column 104 to produce an ion beam 124 that is manipulated by various components (e.g., lenses or the like) in the ion beam optics chamber 122 and directed onto the sample 111 along an ion-optical axis 125.

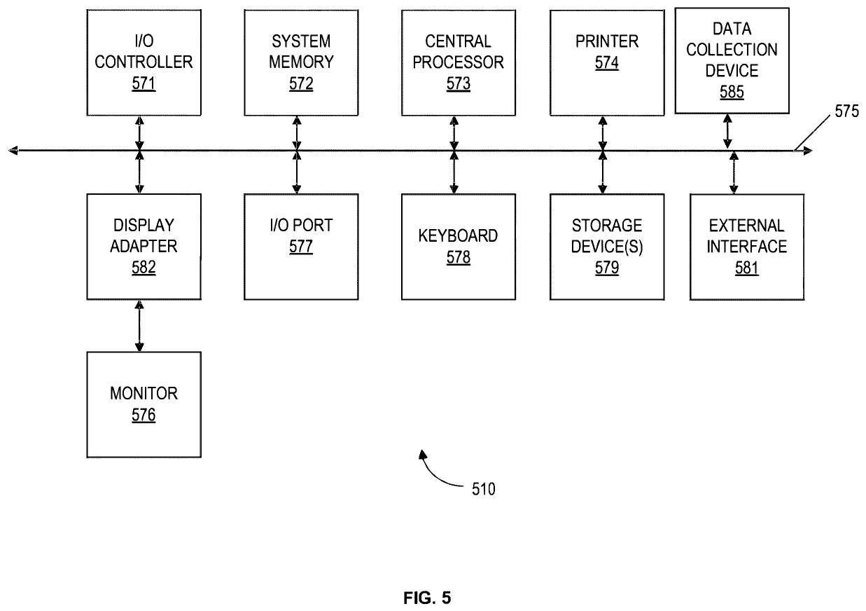

The SEM 102 and the ion beam column 104 can be mounted to a sample chamber 108 housing a movable sample holder 110 for holding the sample 111. The sample chamber 108 can be evacuated using vacuum pumps (not shown). The sample holder 110 can be movable to compensate for variations in the dimensions of the sample 111 and to center the sample 111. The charged particle system 100 may include a computer system 130 (e.g., the computer system 510 depicted in FIG. 5) to provide instructions for operation of the components of the charged particle system 100 (e.g., the SEM 102, the ion beam column 104, the sample chamber 180, or the like). In some embodiments, a control unit 128 may relay instructions from the computer system 130 to certain components of the charged particle system 100 (e.g., the condenser lens 116, the objective lens 106, and the deflection unit 118), however, in other embodiments, the computer system provides instructions to the charged particle system without an intervening control unit.

As discussed above, in conventional systems, the composition of the ion beam 124 can be measured at the sample chamber 108. However, measuring the composition of the ion beam 124 in this manner can be time-intensive and inconsistent. For example, in such a system, the sample chamber 108 would include certain components (e.g., a conductive container, not shown) and modifications (e.g., the objective lens 106 being a magnetic immersion lens and the sample holder 110 including additional electrical connections) that would not always be desirable to conduct operations on the sample 111. Additionally, in this system, the sample chamber 108 would be placed under specific environmental conditions that requires additional complexity to achieve (e.g., placed under a vacuum and movement of various components, such as the conductive container). The configuration of the sample chamber 108 may be hard to consistently replicate given the frequency of changes made in the sample chamber 108 (e.g., the type of the sample holder 110, the height of the sample holder 110, the position of the conductive container, and even the type of sample 111). For these reasons, it may not always be preferable to measure the composition of the ion beam 124 in the sample chamber 108.

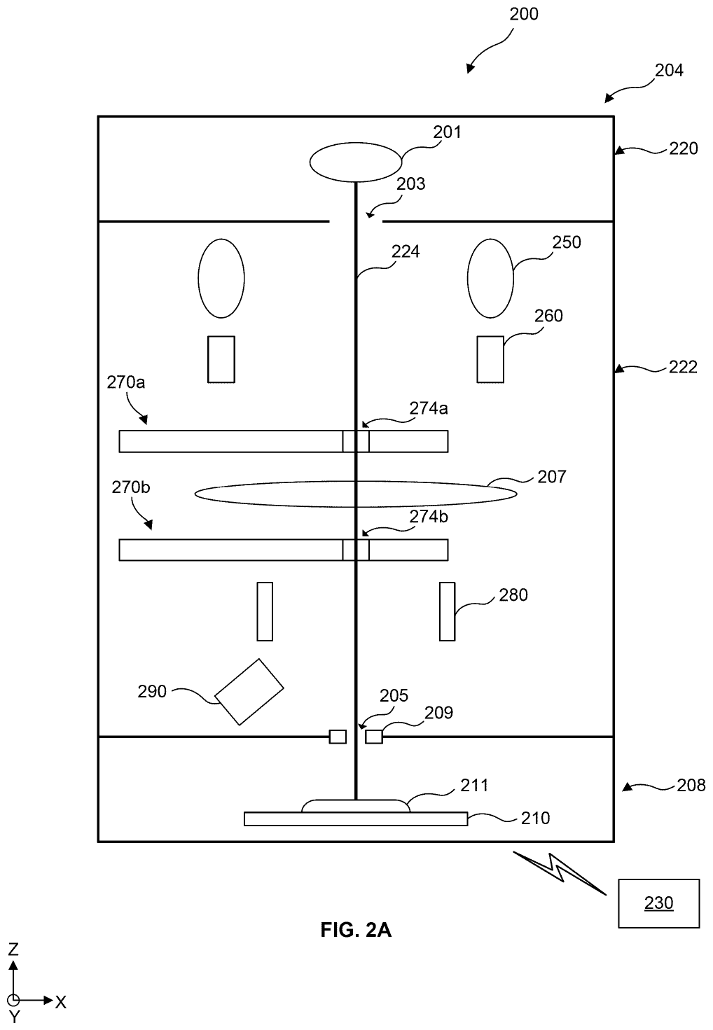

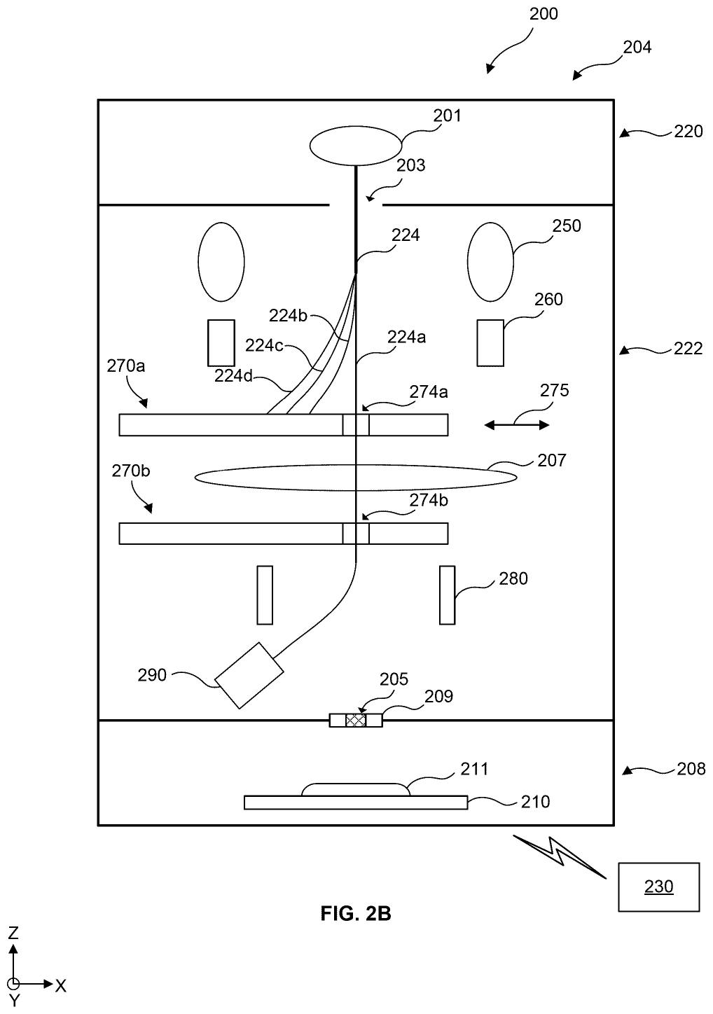

These issues can be addressed by measuring the composition of the ion beam 124 at other locations in the charged particle system 100, such as in the ion beam column 104. For example, FIGS. 2A and 2B depict an example charged particle system 200 including an ion beam column 204 and a sample chamber 208. It is understood that features ending in like reference numerals as features discussed above are similar, except as noted below, and that additional details, such as gas sources coupled to the charged particle system 200, or additional lenses used to alter the shape or direction of an ion beam 224 (e.g., lenses in addition to lens 207) may be omitted. The charged particle system 200 may include a computer system 230 that provides instructions to various components of the charged particle system, such as the ion beam column 204 and the sample chamber 208.

The ion beam column 204 may include an ion source 220. Although not shown, the ion source 220 may be in fluid communication with multiple gas sources and may include the components required to generate a plasma 201 from those multiple gas sources. The ion source 220 may direct a mixed-species ion beam 224 generated from the plasma 201 through a beam inlet 203 into an ion beam optics chamber 222. FIG. 2A depicts a first state of the charged particle system 200, where the ion beam 224 exits the ion beam optics chamber 222 through a beam outlet 205 to interact with the sample 211. As will be discussed further below, FIG. 2B depicts a second state of the charged particle system 200, where the ion beam 224 is deflected prior to exiting the beam outlet 205 to be measured. In this second state, the ion beam column 204 may be fluidly isolated from the sample chamber 208. However, in other embodiments, the ion beam column may not be fluidly isolated from the sample chamber.

Turning specifically to FIG. 2B, the ion beam optics chamber 222 may include an electromagnetic element 250. The electromagnetic element 250 may be one or more magnets that includes multiple magnetic poles (e.g., two magnetic poles). The electromagnetic element 250 may include a coil and/or a magnet to energize the magnetic poles and generate an electromagnetic field between the magnetic poles. In other embodiments, the electromagnetic element may have any other construction or configuration capable of generating the electromagnetic field, as described. For example, the computer system 230 may send instructions to apply a voltage or current to the electromagnetic element 250 to generate the electromagnetic field. The electromagnetic field generated by the electromagnetic element 250 may separate the ion beam 224 into its separate ion species (e.g., a first ion species 224a, a second ion species 224b, a third ion species 224c, and a fourth ion species 224d). Although only four ion species 224a, 224b, 224c, 224d are depicted, in other embodiments, it is understood that more or less than four ion species may be split by the electromagnetic field, such as two, three, five, six, or the like.

The ion beam optics chamber 222 can also include an electrostatic element 260. The electrostatic element can include multiple electrostatic poles (e.g., two electrostatic poles). Each of the electrostatic poles may have a separate applied voltage (e.g., by instructions provided by the computer system 230) to generate an electrostatic field therebetween. The electrostatic field may provide an electrostatic deflection of one or more of the ion species 224a, 224b, 224c, 224d, such as along an XY-plane. The strength of the electrostatic field can be variable to correspond to a desired deflection of each of the ion species 224a, 224b, 224c, 224d. In particular, in some embodiments, the electrostatic field can deflect all of the ion species 224a, 224b, 224c, 224d simultaneously. The electrostatic element 260 can be made from stainless steel, aluminum, brass, silver, gold, platinum, or the like.

In this manner, the electromagnetic element 250 can generate an electromagnetic field to split the ion beam 224 into its separate ion species 224a, 224b, 224c, 224d while the electrostatic element 260 can generate an electrostatic field to electrostatically deflect the separate ion species 224a, 224b, 224c, 224d towards particular locations. A more detailed discussion regarding the functioning and configuration of example electromagnetic elements and electrostatic elements can be found in U.S. Pat. Nos. 8,294,093 and 9,087,671, the contents of each are hereby incorporated by reference in their entirety. However, in other embodiments, the charged particle system may include only one electromagnetic element. For example, an alternative charged particle system may include only the electromagnetic element and no electrostatic element.

The ion beam optics chamber 222 can include a first aperture plate 270a and a second aperture plate 270b that blocks the ion beam 224 from passing through when the aperture plate 270a, 270b intersects the beam path of the ion beam 224. In other embodiments, there may be more or less than two aperture plates, such as one, three, four, or the like. The first aperture plate 270a may define a first aperture 274a and the second aperture plate 270b may define a second aperture 274b that can be aligned with the beam path of a portion or entirety of the ion beam 224 to allow that portion or entirety to pass through. The apertures 274a, 274b can have any shape, such as being a slit, round, square, rectangle, or the like. In other embodiments, each of the aperture plates may define more than one aperture, such as two, three, four or the like. Further, where there is more than one aperture, the apertures can each have a similar or different shape. In yet other embodiments, each of the aperture plates may each define a different amount of apertures compared to the other aperture plates. The apertures 274a, 274b may be sized to allow only a portion of the ion beam 224 to pass through (e.g., to only allow one of the ion species 224a, 224b, 224c, 224d to pass through) and/or may be sized to allow an entirety of the ion beam 224 to pass through. Although each of the apertures 274a, 274b are depicted as having an approximately similar diameter, in other embodiments, each of the apertures may have different diameters. The aperture plates 270a, 270b may be made of a variety of conductive materials, such as tungsten, aluminum, stainless steel, molybdenum, graphite, or some combination of materials.

One or more of the aperture plates 270a, 270b can be moveable within the ion beam optics chamber 222, such as along an XY-plane. For example, the first aperture plate 270a can be movable along a direction as indicated by the arrow 275. In this manner, the aperture plates 270a, 270b can be movable to align the aperture 274a, 274b with the ion beam 224 or ion species 224a, 224b, 224c, 224d to allow the ion beam 224, or one or more ion species 224a, 224b, 224c, 224d to pass through the aperture plate 270a, 270b. This may be particularly useful in embodiments that do not include an electrostatic element (or where the electrostatic element is not actuated to generate an electrostatic field) that generates an electrostatic field to deflect the ion species to a certain position, such as through the aperture. In some embodiments, both of the aperture plates are movable. In other embodiments, only one of the aperture plates is movable (e.g., the first aperture plate).

The ion beam optics chamber 222 can include blankers 280 that are energized by a voltage to generate an electrostatic field to deflect the ion beam 224 toward a desired beam path. For example, the blankers 280 may be energized to generate an electrostatic field that deflects a portion, or the entirety, of the ion beam 224 away from the beam outlet 205, such as toward a different component in the ion beam optics chamber 222. Blankers 280 may be made from conductive materials such as stainless steel, aluminum, bronze, titanium, or other metals. A more detailed discussion regarding blankers can be found in U.S. Pat. No. 5,155,368, the contents of which are hereby incorporated by reference in their entirety.

The ion beam optics chamber 222 can include a conductive container 290 used to measure the current of the ion beam 224, or one or more of the ion species 224a, 224b, 224c, 224d. The conductive container 290 may include a Faraday cup or may include any other component or configuration capable of measuring ion beam current (e.g., any appropriate mechanical and/or electrical components required to enable capturing charged particles and measuring current). The conductive container 290 may be in communication with the computer system 230 such that the computer system 230 can receive the current measurements from the conductive container 290. The conductive container 290 can be made of copper, brass, stainless steel, graphite, or other materials.

The ion beam column 204 can include a valve 209 to open and close the beam outlet 205 (e.g., an isolation valve or the like) such that the ion beam column 204 can be fluidly isolated from the sample chamber 208. In this manner, the sample chamber 208 can be free of the ion beam 224 from the ion beam column 204. This may be beneficial to prevent operations in the ion beam column 204 and the sample chamber 208 from affecting each other. In this manner, operations can be performed within each of the respective ion beam column 204 and the sample chamber 208 without affecting each other (e.g., simultaneously changing samples 211 in the sample chamber 208 while measuring the ion beam 224 in the ion beam column 204).

In use, the valve 209 can be closed to fluidly isolate the ion beam column 204 from the sample chamber 208. The plasma 201 can then generate the ion beam 224 to be directed into the ion beam optics chamber 222. The electromagnetic element 250 can be actuated to cause an electromagnetic field by providing a voltage or current to the electromagnetic element 250. This electromagnetic field splits the ion beam 224 into its constituent ion species 224a, 224b, 224c, 224d.

These ion species 224a, 224b, 224c, 224d may then pass through the apertures 274a, 274b of the aperture plates 270a, 270b. In some embodiments, a voltage may be applied to the electrostatic element 260 to generate a first electrostatic field that deflects one or more of the ion species 224a, 224b, 224c, 224d through the apertures 274a, 274b (e.g., the first aperture 274a). For example, the first electrostatic field may deflect all of the ion species 224a, 224b, 224c, 224d while specifically trying to deflect the first ion species 224a through the first aperture 274a. In another embodiment, the aperture plates 270a, 270b may be movable to align the aperture 274a, 274b with the desired ion species 224a, 224b, 224c, 224d to be measured. For example, the first aperture plate 270a may be moved in a direction of the arrows 275 to align the first ion species 224a with the first aperture 274a. In yet other embodiments, all of the electrostatic element 260 and the aperture plates 270a, 270b may be used. For example, the electrostatic element 260 may generate a first electrostatic field to deflect the first ion species 224a, and the first aperture plate 270a may move in a direction of the arrows 275, such that the first aperture 274a is moved to align with the deflected first ion species 224a. This may be useful when the first electrostatic field is not capable of deflecting the first ion species 224a through the first aperture 274a or to allow for greater precision in alignment between the first ion species 224a and first aperture 274a. In another embodiment, the electromagnetic element 250 may, by itself or in conjunction with the electrostatic element 260, as described above, be adjusted to generate an electric field to direct the first ion species 224a toward the first aperture 274a.

Once the first ion species 224a passes through the aperture plates 274a, 274b, a voltage may be applied to the blankers 280 to actuate the blankers 280 to generate a second electrostatic field such that at least a portion of the first ion species 224a deviates away from the beam outlet 205 toward the conductive container 290. In other embodiments, the ion beam optics chamber may not include blankers (or the blankers may not be actuated) and the conductive container may be movable (e.g., along the XY-plane) to align the first ion species with the conductive container. The conductive container 290 can measure the current of the first ion species 224a and provide these current measurements to the computer system 230 for further analysis. The previous steps may be repeated for each of the other ion species 224b, 224c, 224d until the current of each of the ion species 224a, 224b, 224c, 224d are measured. The computer system 230 can use these measurements to correlate a mass or flow rate, or pressure of the gas species with the resultant current of each ion species 224a, 224b, 224c, 224d. If the ratio of ion species 224a, 224b, 224c, 224d is unsatisfactory, the mass or flow rate, or pressure of the gas species may be adjusted to change the ratio of ion species 224a, 224b, 224c, 224d until a desired composition of the ion beam 224 is reached.

The computer system 230 may also store the current measurements of each ion species 224a, 224b, 224c, 224d, and the corresponding input parameters (e.g., the mass or flow rate/pressure of each of the gas species to control the gas composition, radiofrequency (RF) power provided to the plasma 201, total pressure of the gas mixture, or the like) used to generate each of the ion species 224a, 224b, 224c, 224d, in a database (e.g., an estimate table) so that, in the future, it may be easier to predict what input parameters used to generate the ion beam 224 will result in the desired ratio and amount of each ion species 224a, 224b, 224c, 224d, thus requiring less trial and error to generate the ion beam 224 having a desired composition of ion species 224a, 224b, 224c, 224d. A more detailed discussion regarding the system and method of mixing gases is described in U.S. patent application Ser. No. 18/393,061 (the “'061 Application”), the contents of which are hereby incorporated by reference in their entirety.

Turning to FIG. 2A, once the ion beam 224 is measured and a desired ion beam 224 composition is achieved, the electromagnetic element 250 can be deactivated such that the ion species 224a, 224b, 224c, 224d are no longer split. Additionally, the electrostatic element 260 and blankers 280 can be deactivated (if previously activated) and the valve 209 opened. The whole ion beam 224 can then flow past the electromagnetic element 250, the electrostatic element 260, the aperture plates 270a, 270b, and the blankers 280 to perform operations on the sample 211.

Measuring the current of each ion species 224a, 224b, 224c, 224d in the ion beam column 204, rather than in the sample chamber 208 offers a number of benefits. For example, maintaining the desired ion species for the ion beam 224 requires less re-calibration (e.g., by changing the flow rate, pressure, or mass of gas species used to generate the ion beam 224) because the ion beam column 204 is a more controlled environment than the sample chamber 208 and is not affected by certain changing variables that can alter the resultant ion species 224a, 224b, 224c, 224d or proportions thereof from the gas species used in generating the plasma 201. Specifically, the ion beam column 204 is not affected by variables that would affect the sample chamber 208, such as the type and position of the sample holder 210, the position of a conductive container (not shown) in the sample chamber 208, the changing magnetic field in the sample chamber 208, and the position and type of sample 211. If the ion beam 224 were measured in the sample chamber 208, all these changing variables would require that the measurement be re-calibrated following any configuration change in the sample chamber (e.g., change of sample 211, type and position of the sample holder 210, or change in the magnetic field or magnetic environment of the sample chamber due to events such as the insertion or retraction of detectors (not shown)). As such, measuring the ion beam 224 in the ion beam column 204 requires less re-calibration and, thus, provides a more consistent ion beam 224 with greater ease.

Additionally, when the valve 209 is closed to fluidly isolate the sample chamber 208 and the ion beam column 204 from each other, different operations can be performed within each of the respective locations simultaneously. For example, the ion beam 224 can be measured and have its composition changed, as discussed above, while changes are made in the sample chamber 208 (e.g., changes to, or substitution of, the sample 211, the type and position of the sample holder 210, or the like) or other imaging or analysis operations are ongoing in the sample chamber 208 (such as imaging the sample 211 using the SEM column). Alternatively, the ion beam 224 can be measured while no changes are made in the sample chamber 208 (e.g., the sample 211 and the sample holder 210 can be maintained in place). In both cases, such operations can decrease the amount of time that the charged particle system 200 is inactive compared to conventional systems, where the operation of both the ion beam column and the sample chamber would have to be stopped in order to perform any ion beam measurement and calibration, or sample changing.

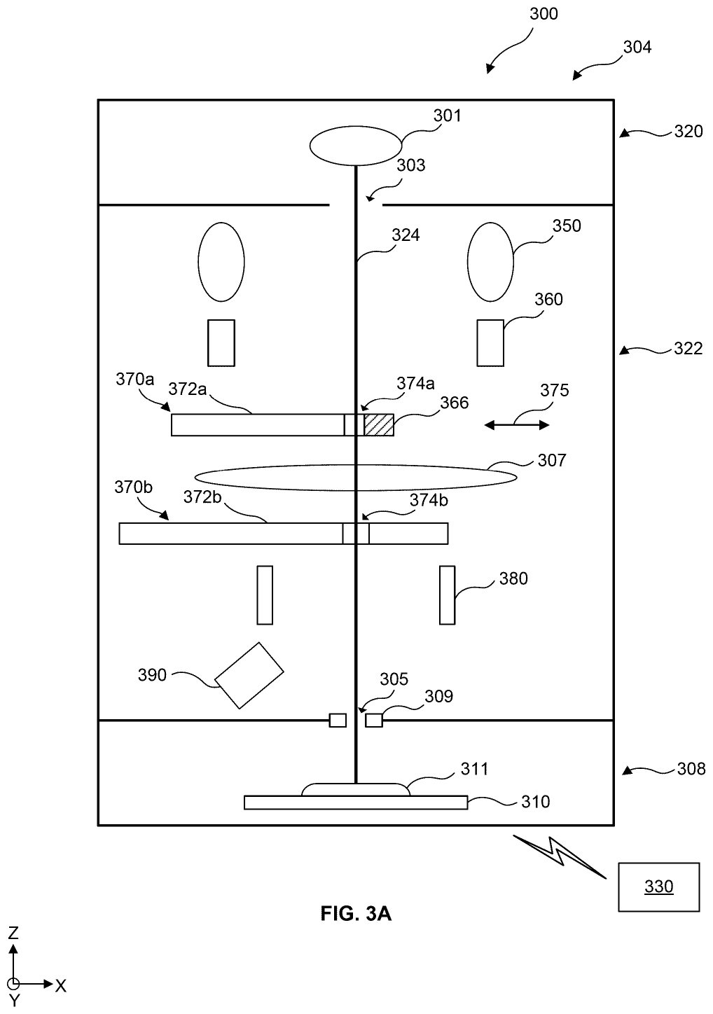

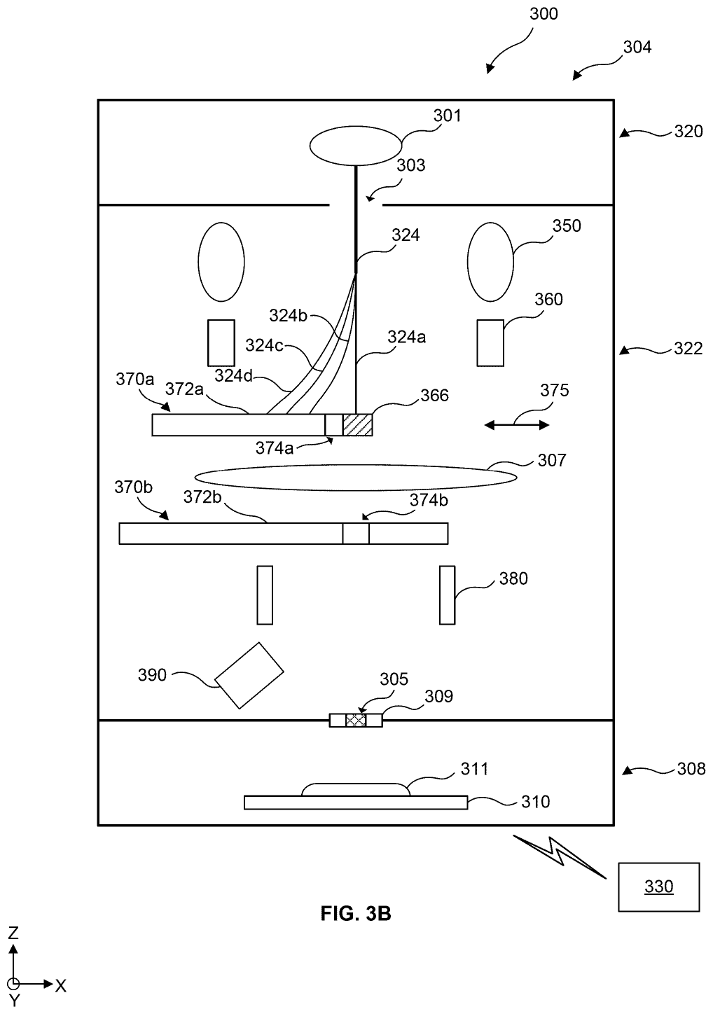

In an alternative embodiment, the current of the ion species 224a, 224b, 224c, 224d may be measured in a second conductive container positioned on or coupled to one of the aperture plates 270a, 270b in addition to, or alternatively from, the conductive container 290. For example, FIGS. 3A and 3B depict an example charged particle system 300 including an ion beam column 304 and a sample chamber 308. It is understood that features ending in like reference numerals as features discussed above are similar (e.g., the plasma 301, the beam inlet 303, the lens 307, the valve 309, the sample holder 310, the sample 311), except as noted below. Although the ion beam column 304 includes a first conductive container 390, the first conductive container 390 may not be used for measuring the ion beam 324 and, instead, may be used for other operations. However, in other embodiments, the first conductive container may also be used to measure the ion beam in addition to other operations.

The first aperture plate 370a may include a first body 372a and a second conductive container 366, and may define a first aperture 374a. The first body 372a may block the beam 324 from passing through when the first body 372a intersects the beam path of the ion beam 324. The second conductive container 366 may measure a current of the ion beam 324 or a portion thereof (e.g., the ion species 324a, 324b, 324c, 324d). The first aperture 374a may be aligned with the beam path to allow a portion or entirety of the ion beam 324 to pass through. Although the first aperture 374a is depicted as being defined between the first body 372a and the second conductive container 366, in other embodiments, the first aperture may be defined by the body or the second conductive container. As noted previously, the second aperture plate 370b can include a second body 372b and second aperture 374b similar to the first aperture plate 370a. Although the second conductive container 366 is depicted as being in line with the first body 372a, in yet other embodiments, the second conductive container may be below or above the first body along the Z-axis. In other embodiments, the second conductive container is a separate component from the first aperture plate that is coupled, along the Z-axis, on top of, in line with, or below the first aperture plate. In an even further embodiment, the second aperture plate can include a third conductive container coupled to, or a part of, the second aperture plate, similar to the first aperture plate. In another embodiment, the second conductive container may be coupled to, or be a part of, the second aperture plate rather than the first aperture plate.

FIG. 3A depicts a first state of the charged particle system 300, where the ion beam 324 passes through the aperture plates 370a, 370b and exits the ion beam optics chamber 322 through a beam outlet 305 to interact with the sample 311. FIG. 3B depicts a second state of the charged particle system 300, where the ion beam 324 is deflected prior to exiting the beam outlet 305 to be measured by the second conductive container 366. Turning specifically to FIG. 3B, once the electromagnetic element 350 is actuated to generate an electromagnetic field to split the ion beam 324 into the ion species 324a, 324b, 324c, 324d, one of the ion species 324a, 324b, 324c, 324d (e.g., the first ion species 324a) can be aligned with the second conductive container 366 for measurement. For example, the second aperture plate 370a can be moved along the XY-plane (e.g., in a direction along arrow 375) and/or the electrostatic element 360 can be actuated to generate an electrostatic field that deflects the ion species 324a, 324b, 324c, 324d such that one of the ion species 324a, 324b, 324c, 324d is aligned with the second conductive container 366 until the currents of one or more of the ion species 324a, 324b, 324c, 324d are measured.

Such a configuration may be beneficial in further ensuring the consistency of the ion beam 324 measurement because rather than measuring the ion species 324a, 324b, 324c, 324d at the first conductive container 390, measuring the ion species 324a, 324b, 324c, 324d at the second conductive container 366 is further away from the beam outlet 305, thus further minimizing the risk of contaminants or variables from the sample chamber 308 interfering with the measurement of the ion species 324a, 324b, 324c, 324d. Additionally, certain components may not be required, such as the blankers 380, thus saving room in the ion beam column 304.

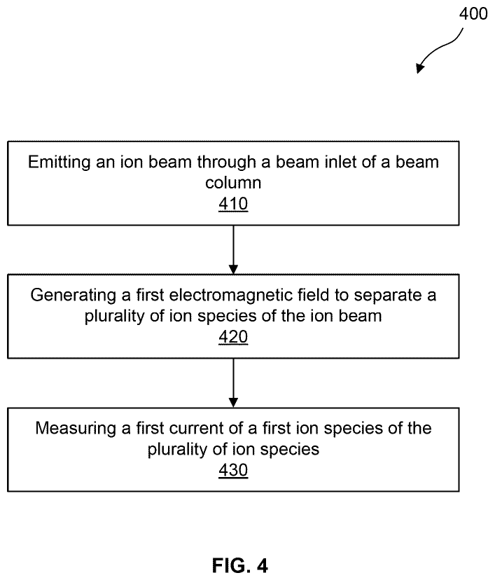

FIG. 4 depicts an example flowchart showing a process 400 for measuring ion species of an ion beam. It is understood that features ending in like reference numerals as features discussed above are similar, except as noted below. Unless specified otherwise, the flowchart in FIG. 4 will be described with reference to the charged particle system 200 shown in FIGS. 2A and 2B. The below operation of the components of the charged particle system 200 can be performed by the computer system 230.

Turning to Step 410, an ion source 220 may emit an ion beam 224 through a beam inlet 203 of an ion beam column 204. Specifically, a plurality of gas species from a plurality of gas sources may be combined and ionized to form a plasma 201. The plasma 201 may generate the ion beam 224 which is then directed through the beam inlet 203. The ion beam 224 may be made of a plurality of ion species 224a, 224b, 224c, 224d that each correspond to a gas species used to form the plasma 201. In some embodiments, a valve 209 may be closed to fluidly isolate the ion beam column 204 from the sample chamber 208.

Turning to Step 420, an electromagnetic element 250 may generate an electromagnetic field to separate the plurality of ion species 224a, 224b, 224c, 224d of the ion beam 224. Turning specifically to FIG. 2B, in some embodiments, an electrostatic element 260 may generate a first electrostatic field to electrostatically deflect the first ion species 224a toward a first aperture 274a of a first aperture plate 270a so that the first ion species 224a passes through the first aperture plate 270a. In other embodiments, the first aperture plate 270a may move in a direction along the arrow 275 to align the first aperture 274a with the first ion species 224a. In yet other embodiments, the electrostatic element 260 may generate the first electrostatic field to deflect the first ion species 224a and the first aperture plate 270a may move such that the first ion species 224a is aligned with the first aperture 274a. In yet other embodiments, the second aperture plate 270b may also move (e.g., along an XY-plane) to align the first ion species 224a with the second aperture 274b of the second aperture plate 270b. In a yet further embodiment, blankers 280 may generate a second electrostatic to deflect the first ion species 224a toward a conductive container 290.

Turning to Step 430, the conductive container 290 may measure a first current of a first ion species 224a of the plurality of ion species 224a, 224b, 224c, 224d. Steps 420 and 430 may be repeated for each of the rest of the ion species 224b, 224c, 224d. With specific reference to FIGS. 3A and 3B, the second conductive container 366 may measure the first current of the first ion species 224a. Turning back to FIGS. 2A and 2B, the computer system 230 may receive these current measurements to determine a first mass flow or first flow rate or first pressure of the gas species corresponding to the first ion species 224a. The computer system 230 may store the current measurements of each of the ion species 224a, 224b, 224c, 224d and the mass/flow rate, or pressure of each of the gas species in an estimate table. In some embodiments, such as when the composition of the ion beam 224 is unsatisfactory, the mass/flow rate or pressure of one or more of the gas species may be adjusted based on the current measurements of the ion species 224a, 224b, 224c, 224d to generate a second ion beam. The above steps may be repeated until an ion beam having the desired composition for operation on the sample 211 is generated.

Any of the computer systems mentioned herein (e.g., the computer systems 130, 230, 330) may utilize any suitable number of subsystems. Examples of such subsystems are shown in FIG. 5 in computer system 510. In some embodiments, a computer system includes a single computer apparatus, where the subsystems can be the components of the computer apparatus. In other embodiments, a computer system can include multiple computer apparatuses, each being a subsystem, with internal components. A computer system can include desktop and laptop computers, tablets, mobile phones and other mobile devices.

The subsystems shown in FIG. 5 are interconnected via a system bus 575. Additional subsystems such as a printer 574, keyboard 578, storage device(s) 579, monitor 576 (e.g., a display screen, such as an LED), which is coupled to display adapter 582, and others are shown. Peripherals and input/output (I/O) devices, which couple to I/O controller 571, can be connected to the computer system by any number of means known in the art such as input/output (I/O) port 577 (e.g., USB, Fire Wire®). For example, I/O port 577 or external interface 581 (e.g., Ethernet, Wi-Fi, etc.) can be used to connect computer system 510 to a wide area network such as the Internet, a mouse input device, or a scanner. The interconnection via system bus 575 allows the central processor 573 to communicate with each subsystem and to control the execution of a plurality of instructions from system memory 572 or the storage device(s) 579 (e.g., a fixed disk, such as a hard drive, or optical disk), as well as the exchange of information between subsystems. The system memory 572 and/or the storage device(s) 579 may embody a computer readable medium. Another subsystem is a data collection device 585, such as a camera, microphone, accelerometer, and the like. Any of the data mentioned herein can be output from one component to another component and can be output to the user.

A computer system can include a plurality of the same components or subsystems, e.g., connected together by external interface 581, by an internal interface, or via removable storage devices that can be connected and removed from one component to another component. In some embodiments, computer systems, subsystem, or apparatuses can communicate over a network. In such instances, one computer can be considered a client and another computer a server, where each can be part of a same computer system. A client and a server can each include multiple systems, subsystems, or components.

Aspects of embodiments can be implemented in the form of control logic using hardware circuitry (e.g., an application specific integrated circuit or field programmable gate array) and/or using computer software stored in a memory with a generally programmable processor in a modular or integrated manner, and thus a processor can include memory storing software instructions that configure hardware circuitry, as well as an FPGA with configuration instructions or an ASIC. As used herein, a processor can include a single-core processor, multi-core processor on a same integrated chip, or multiple processing units on a single circuit board or networked, as well as dedicated hardware. Based on the disclosure and teachings provided herein, a person of ordinary skill in the art will know and appreciate other ways and/or methods to implement embodiments of the present disclosure using hardware and a combination of hardware and software.

Any of the software components or functions described in this application, such as processes 400, 500, 600 or 700, may be implemented as software code to be executed by a processor using any suitable computer language such as, for example, Java, C, C++, C#, Objective-C, Swift, or scripting language such as Perl or Python using, for example, conventional or object-oriented techniques. The software code may be stored as a series of instructions or commands on a computer readable medium for storage and/or transmission. A suitable non-transitory computer readable medium can include random access memory (RAM), a read only memory (ROM), a magnetic medium such as a hard-drive or a floppy disk, or an optical medium such as a compact disk (CD) or DVD (digital versatile disk) or Blu-ray disk, flash memory, and the like. The computer readable medium may be any combination of such devices. In addition, the order of operations may be re-arranged. A process can be terminated when its operations are completed, but could have additional steps not included in a figure. A process may correspond to a method, a function, a procedure, a subroutine, a subprogram, etc. When a process corresponds to a function, its termination may correspond to a return of the function to the calling function or the main function

Such programs may also be encoded and transmitted using carrier signals adapted for transmission via wired, optical, and/or wireless networks conforming to a variety of protocols, including the Internet. As such, a computer readable medium may be created using a data signal encoded with such programs. Computer readable media encoded with the program code may be packaged with a compatible device or provided separately from other devices (e.g., via Internet download). Any such computer readable medium may reside on or within a single computer product (e.g., a hard drive, a CD, or an entire computer system), and may be present on or within different computer products within a system or network. A computer system may include a monitor, printer, or other suitable display for providing any of the results mentioned herein to a user.

Any of the methods described herein may be totally or partially performed with a computer system including one or more processors, which can be configured to perform the steps. Any operations performed with a processor (e.g., aligning, determining, comparing, computing, calculating) may be performed in real-time. The term “real-time” may refer to computing operations or processes that are completed within a certain time constraint. The time constraint may be 1 minute, 1 hour, 1 day, or 7 days. Thus, embodiments can be directed to computer systems configured to perform the steps of any of the methods described herein, potentially with different components performing a respective step or a respective group of steps. Although presented as numbered steps, steps of methods herein can be performed at a same time or at different times or in a different order. Additionally, portions of these steps may be used with portions of other steps from other methods. Also, all or portions of a step may be optional. Additionally, any of the steps of any of the methods can be performed with modules, units, circuits, or other means of a system for performing these steps.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom” or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In some implementations, operations or processing may involve physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the discussion herein, it is appreciated that throughout this specification discussions utilizing terms such as “processing,” “computing,” “calculating,” “determining,” or the like refer to actions or processes of a specific apparatus, such as a special purpose computer, special purpose computing apparatus or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A charged particle system, comprising:
a plasma source configured to generate an ion beam including a plurality of ion species; and
an ion beam optics chamber in fluid communication with the plasma source, wherein the ion beam optics chamber includes:
an electromagnetic element configured to generate a first magnetic field to separate each of the ion species of the plurality of ion species; and
a conductive container configured to measure a first current corresponding to a first ion species of the plurality of ion species.

2. The charged particle system of claim 1, further comprising a computer system in communication with the conductive container, wherein the computer system is configured to determine a first mass of a first gas species corresponding to the first ion species based on the first current.

3. The charged particle system of claim 1, further comprising a sample chamber including a sample holder, wherein:
in a first state, the plasma source generates the ion beam and the ion beam is directed to the sample holder; and
in a second state, the electromagnetic element generates the first magnetic field and the sample chamber is free of the ion beam.

4. The charged particle system of claim 3, wherein, in the second state, the ion beam optics chamber and the sample chamber are fluidly isolated from each other.

5. The charged particle system of claim 1, further comprising an aperture plate that defines an aperture configured to receive the first ion species while the aperture plate is configured to block other ion species of the plurality of ion species.

6. The charged particle system of claim 5, further comprising an electrostatic element configured to generate an electrostatic field to deflect the first ion species toward the aperture of the aperture plate.

7. The charged particle system of claim 5, wherein the aperture plate is movable to align the aperture with the first ion species.

8. The charged particle system of claim 5, wherein the aperture plate includes the conductive container.

9. A charged particle system, comprising:
a plasma source; and
an ion beam optics chamber including an electromagnetic element configured to generate a first magnetic field to separate a plurality of ion species of the ion beam and a conductive container configured to measure a first current of a first ion species of the plurality of ion species, wherein:
the ion beam optics chamber defines a beam inlet and a beam outlet;
in a first state, the plasma source is configured to emit the ion beam through the beam inlet and the beam outlet; and
in a second state:
the plasma source is configured to emit the ion beam through the beam inlet; and
at least a portion of the first ion species deviates away from the beam outlet toward the conductive container.

10. The charged particle system of claim 9, further comprising a sample chamber including a sample holder, wherein:
in the first state, the ion beam optics chamber and the sample chamber are in fluid communication with each other; and
in the second state, the ion beam optics chamber and the sample chamber are fluidly isolated from each other.

11. The charged particle system of claim 9, further comprising a computer system in communication with the conductive container, wherein the computer system is configured to determine a first mass of a first gas species of the first ion species based on the first current.

12. The charged particle system of claim 9, further comprising an aperture plate that defines an aperture configured to receive the first ion species while the aperture plate is configured to block other ion species of the plurality of ion species.

13. The charged particle system of claim 12, further comprising an electrostatic element configured to generate an electrostatic field to deflect the first ion species toward the aperture of the aperture plate.

14. The charged particle system of claim 12, wherein the aperture plate is movable to align the aperture with the first ion species.

15. The charged particle system of claim 12, wherein the aperture plate includes the conductive container.

16. A method of measuring ion species, comprising:
emitting, from a plasma housed in an ion source generated from a plurality of gas species, an ion beam through a beam inlet of an ion beam optics chamber;
generating, using an electromagnetic element in the ion beam optics chamber, an electromagnetic field to separate a plurality of ion species of the ion beam; and
measuring, using a conductive container in the ion beam optics chamber, a first current of a first ion species of the plurality of ion species.

17. The method of claim 16, wherein the ion beam is a first ion beam, the method further comprising:
adjusting a first flow rate of a first gas species of the plurality of gas species corresponding to the first ion species based on the first current; and
after adjusting the first flow rate, emitting a second beam from the plasma.

18. The method of claim 16, further comprising receiving the first ion species through an aperture defined by an aperture plate.

19. The method of claim 18, further comprising generating, using an electrostatic element, a first electrostatic field to deflect the first ion species toward the aperture.

20. The method of claim 19, further wherein measuring the first current of the first ion species is performed while the ion beam optics chamber is fluidly isolated from a sample chamber.
